(19) United States
(12) Patent Application Publication
(10) Pub. No.: US 2015/0255741 A1
(43) Pub. Date: Sep. 10, 2015

(54) ORGANIC LIGHT EMITTING DIODE DEVICE

(71) Applicant: SAMSUNG DISPLAY CO., LTD., Yongin-City (KR)

(72) Inventors: Heun Seung Lee, Suwon-si (KR); Sang Woo Pyo, Hwaseong-si (KR); Hyo Yeon Kim, Hwaseong-si (KR); Hye Yeon Shim, Seoul (KR); Ji Hwan Yoon, Yongin-si (KR); Sang Woo Lee, Hwaseong-si (KR); Kyul Han, Seoul (KR)

(21) Appl. No.: 14/448,973

(22) Filed: Jul. 31, 2014

(30) Foreign Application Priority Data
Mar. 6, 2014 (KR) 10-2014-0026685

(51) Int. Cl. H01L 51/50

(52) U.S. Cl. CPC H01L 51/5004; H01L 51/506

(57) ABSTRACT

An organic light emitting diode device includes: an anode; a hole auxiliary layer on one side of the anode; an emission layer on one side of the hole auxiliary layer; and a cathode on one side of the emission layer; the hole auxiliary layer including: a hole injection layer; a hole transport layer; a first hole transport auxiliary layer between the hole injection layer and the hole transport layer and including a first p-type dopant and a first host having a first HOMO level; and a second hole transport auxiliary layer between the hole injection layer and the hole transport layer and including a second p-type dopant and a second host having a second HOMO level different from the first HOMO level.

### CROSS-REFERENCE TO RELATED APPLICATION

This application claims priority to and the benefit of Korean Patent Application No. 10-2014-0026685 filed in the Korean Intellectual Property Office on Mar. 6, 2014, the entire content of which is incorporated herein by reference.

### BACKGROUND

1. Field

An organic light emitting diode device is disclosed.

2. Description of the Related Art

Recent demand for reduced size and thickness of monitors, televisions, and the like has promoted replacement of a cathode ray tube (CRT) with a liquid crystal display (LCD). However, the liquid crystal display (LCD) uses a separate backlight as it is a non-emissive device and also has limits in terms of a response speed, a viewing angle, and the like.

Recently, these disadvantages have been expected to be overcome by an organic light emitting diode device (OLED) display.

An organic light emitting diode device includes two electrodes and an organic layer therebetween. The organic layer includes an emission layer. The organic light emitting diode device emits light when electrons injected from one of the electrodes are combined in the emission layer with holes injected from another one of the electrodes and, thus, form excitons and release energy.

### SUMMARY

One embodiment relates to an organic light emitting diode device capable of lowering a driving voltage and increasing the efficiency of the organic light emitting diode device by increasing charge mobility.

According to one embodiment, an organic light emitting diode device includes: an anode; a hole auxiliary layer on one side of the anode; an emission layer on one side of the hole auxiliary layer; and a cathode on one side of the emission layer, the hole auxiliary layer including: a hole injection layer; a hole transport layer; a first hole transport auxiliary layer between the hole injection layer and the hole transport layer and including a first p-type dopant and a first host having a first HOMO level, and a second hole transport auxiliary layer between the hole injection layer and the hole transport layer and including a second p-type dopant and a second host having a second HOMO level different from the first HOMO level.

The second HOMO level may be higher than the first HOMO level.

The hole transport layer may include a host that is the same as the second host.

The second hole transport auxiliary layer may directly contact the hole transport layer.

The first HOMO level and the second HOMO level may each be about 5.0 eV to about 5.5 eV.

The hole auxiliary layer may be stacked in the order of the hole injection layer, the first hole transport auxiliary layer, the second hole transport auxiliary layer, and the hole transport layer.

The organic light emitting diode device may further include a blue common layer between the hole injection layer and the first hole transport auxiliary layer.

The first p-type dopant of the first hole transport auxiliary layer may be included in an amount of about 0.01 to about 20 parts by weight based on 100 parts by weight of the first host.

The second p-type dopant of the second hole transport auxiliary layer may be included in an amount of about 0.01 to about 20 parts by weight based on 100 parts by weight of the second host.

The first p-type dopant or the second p-type dopant may include a quinone derivative, a metal oxide, a cyano-containing compound, or a combination thereof.

The first p-type dopant or the second p-type dopant may include tetracyanoquinone dimethane (TCNQ), 2,3,5,6-tetrafluoro-tetracyano-1,4-benzoquinone dimethane (F4-TCNQ), a tungsten oxide, a molybdenum oxide, or a combination thereof.

As the charge mobility is increased, the driving voltage may be decreased, and the efficiency of the organic light emitting diode device may be enhanced.

### BRIEF DESCRIPTION OF THE DRAWINGS

The accompanying drawings, together with the specification, illustrate embodiments of the present disclosure, and, together with the description, serve to explain the principles of the present disclosure.

FIG. 1 is a cross-sectional view showing an organic light emitting diode device according to one embodiment.

FIG. 2 is a schematic view showing one example of energy level of the organic light emitting diode device shown in FIG. 1.

FIG. 3 is a cross-sectional view showing the organic light emitting diode device according to another embodiment.

FIG. 4 is a cross-sectional view showing the organic light emitting diode device according to further another embodiment.

FIG. 5 is a schematic view showing one example of energy level of the organic light emitting diode device shown in FIG. 4.

FIG. 6 is a graph showing efficiency of the organic light emitting diode devices according to Example 1, Example 2, and Comparative Example.

### DETAILED DESCRIPTION

The present disclosure will be described more fully hereinafter with reference to the accompanying drawings, in which example embodiments of this disclosure are shown. However, this disclosure may be embodied in many different forms and should not be construed as being limited to the example embodiments set forth herein.

In the drawings, the thicknesses of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or be indirectly on the other element with one or more intervening elements therebetween. In contrast, when an element is referred to as being “directly on” another element, there are no intervening elements present.

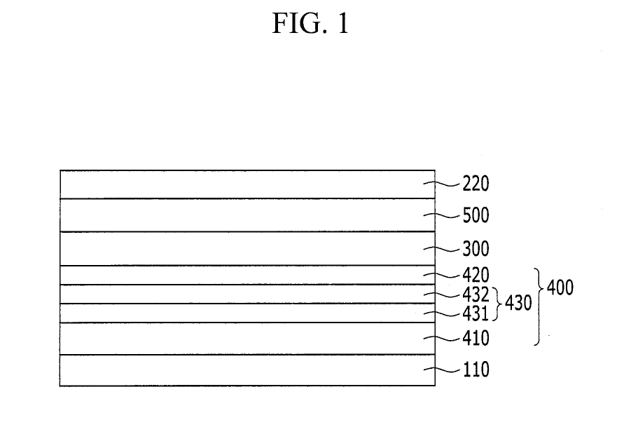

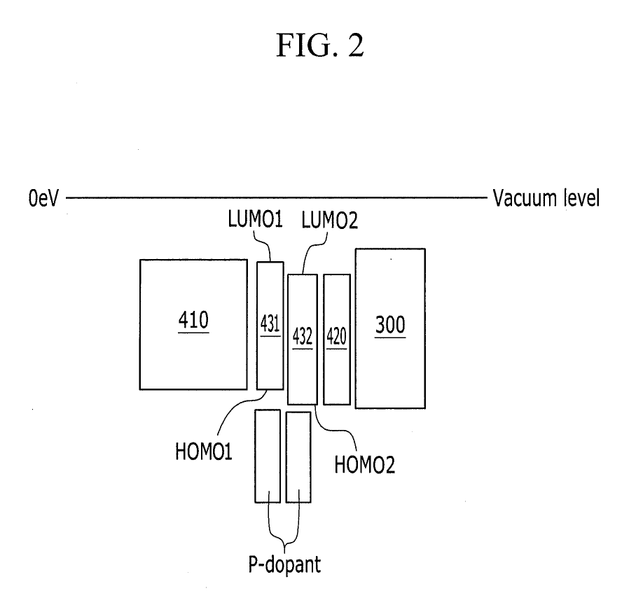

Hereinafter, an organic light emitting diode device in accordance with one embodiment will be described with reference to FIG. 1 and FIG. 2.

FIG. 1 is a cross-sectional view showing an organic light emitting diode device according to one embodiment, and FIG. 2 is a schematic view showing one example of energy levels of the organic light emitting diode device shown in FIG. 1.

Referring to FIG. 1, the organic light emitting diode device according to one embodiment includes an anode 110, a hole auxiliary layer 400 on (e.g., positioned on) one side of the anode 110, an emission layer 300 on (e.g., positioned on) one side of the hole auxiliary layer 400, an electron auxiliary layer 500 on (e.g., positioned on) one side of the emission layer 300, and a cathode 220 on (e.g., positioned on) one side of the electron auxiliary layer 500.

The anode 110 may include (or be made of) a transparent or opaque conductor. The transparent conductor may include (or be), for example, a metal thin film having a thin thickness, for example about 1 nm to about 50 nm, or a conductive oxide such as ITO, IZO, or a combination thereof; and the opaque conductor may include (or be) a metal, for example, aluminum (Al), silver (Ag), or a combination thereof, but the transparent conductor and opaque conductor are not limited thereto. When the lower electrode (e.g., the anode 110) is a transparent electrode, the light may be emitted from the lower part of the organic light emitting diode device as a bottom emission device.

The hole auxiliary layer 400 includes a hole injection layer (HIL) 410, a hole transport layer (HTL) 420, and a hole transport auxiliary layer 430 between the hole injection layer (HIL) 410 and the hole transport layer (HTL) 420.

The hole injection layer (HIL) 410 may facilitate hole injection from the anode 110 to enhance hole mobility in the organic light emitting diode device.

The hole transport layer (HTL) 420 is adjacent to the emission layer 300 to increase hole mobility into the emission layer 300.

The hole transport auxiliary layer 430 includes a first hole transport auxiliary layer 431 disposed closely to (or adjacent to) the hole injection layer 410 and a second hole transport auxiliary layer 432 disposed closely to (or adjacent to) the hole transport layer 420.

The first hole transport auxiliary layer 431 and the second hole transport auxiliary layer 432 may each include a p-type dopant, and be between the hole injection layer 410 and the hole transport layer 420 to increase the number of holes injected into the hole transport layer 420, so as to improve the hole mobility and the mobile capacity into the emission layer 300.

In this case, the first hole transport auxiliary layer 431 and the second hole transport auxiliary layer 432 include materials having energy levels that are different from each other. In other words, the first hole transport auxiliary layer 431 may include a first host having a first HOMO level and a p-type dopant; and the second hole transport auxiliary layer 432 may include a second host having a second HOMO level, different from the first HOMO level, and a p-type dopant. For example, the second HOMO level may be higher than the first HOMO level.

Referring to FIG. 2, the first hole transport auxiliary layer 431 and the second hole transport auxiliary layer 432 each include a host and a p-type dopant. The second hole transport auxiliary layer 432 may have a HOMO level (e.g., HOMO2) higher than the HOMO level (e.g., HOMO1) of the first hole transport auxiliary layer 431. The higher HOMO level means the high absolute value of energy level when the vacuum level is reference (0 eV). For example, as described herein, a HOMO level is higher than an other HOMO level when the HOMO level is further away in energy from the reference vacuum level than the other HOMO level. Thus, the HOMO levels are described herein using absolute values of energies relative to the reference vacuum level.

As the electron mobility is effectively suppressed (or reduced), and the hole mobility is effectively enhanced by including the first hole transport auxiliary layer 431 and the second hole transport auxiliary layer 432 having different HOMO levels, the driving voltage may be decreased, and the efficiency may be improved.

The host of the first hole transport auxiliary layer 431 and the host of the second hole transport auxiliary layer 432 may each have a HOMO level of about 5.0 eV to about 5.5 eV and may be satisfied with, for example, Relationship Equation 1. For example, the first host may have a first HOMO level having an energy of about 5.0 eV to about 5.5 eV (or less than about 5.5 eV) and the second host may have a second HOMO level having an energy of about 5.0 eV (or more than 5.0 eV) to about 5.5 eV.

5.0 eV≦first HOMO level 5 second HOMO level≦5.5 Ev Relationship Equation 1

The host of the first hole transport auxiliary layer 431 (e.g., the first host) and the host of the second hole transport auxiliary layer 432 (e.g., the second host) may each have a LUMO level of less than or equal to about 2.5 eV. By having a LUMO level in the foregoing range, electron mobility to the anode 410 may be effectively suppressed (or reduced). The LUMO level of the first hole transport auxiliary layer 431 is shown as LUMO1 in FIG. 2, and the LUMO level of the second hole transport auxiliary layer 432 is shown as LUMO2 in FIG. 2.

For example, the p-type dopant may be selected from a quinone derivative, a metal oxide, a cyano-containing compound, or a combination thereof, but the present disclosure is not limited thereto. The quinone compound may include, for example, tetracyanoquinone dimethane (TCNQ), 2,3,5,6-tetrafluoro-tetracyano-1,4-benzoquinone dimethane (F4-TCNQ), or a combination thereof; the metal oxide may include, for example, a tungsten oxide, a molybdenum oxide, or a combination thereof; and the cyano-containing compound may include, for example, the following compound HT-D1, but the present disclosure is not limited thereto.

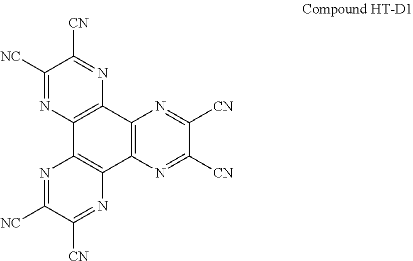 [SMILES: N#Cc1nc2c3nc(C#N)c(C#N)nc3c3nc(C#N)c(C#N)nc3c2nc1C#N]

The p-type dopant of the first hole transport auxiliary layer 431 may be included in an amount of about 0.01 to about 20 parts by weight based on 100 parts by weight of the host; and the p-type dopant of the second hole transport auxiliary layer 432 may be included in an amount of about 0.01 to about 20 parts by weight based on 100 parts by weight of the host.

The hole transport layer (HTL) 420 may include the same material as the host of second hole transport auxiliary layer 432 (e.g., the HTL 420 may include the second host).

The emission layer 300 may include (or be made of) an organic material inherently capable of emitting a light among three primary colors such as red, green, blue, and the like, or a mixture of an inorganic material and the organic material such as, for example, a polyfluorene derivative, a (poly)paraphenylenevinylene derivative, a polyphenylene derivative, a polyfluorene derivative, a polyvinylcarbazole, a polythiophene derivative, or a compound prepared by doping the foregoing material (e.g., the foregoing polymer materials) with a perylene-based pigment, a cumarine-based pigment, a rothermine-based pigment, rubrene, perylene, 9,10-diphenylanthracene, tetraphenylbutadiene, Nile red, coumarin, quinacridone, and the like, but the present disclosure is not limited thereto. An organic light emitting device displays an image by a spatial combination of primary colors emitted by an emission layer therein.

The emission layer 300 may emit white light by combining basic colors such as three primary colors of red, green, and blue, and in this case, the color coordination may emit white light by combining the colors of adjacent pixels or by combining colors laminated in a perpendicular direction.

The electron auxiliary layer 500 may be between the emission layer 300 and the cathode 220 to enhance the electron mobility, so as to improve the luminous efficiency of the organic light emitting diode device. The electron auxiliary layer 500 may include an electron injection layer (EIL), an electron transport layer (ETL), a hole blocking layer (HBL) or the like, and may include a combination thereof. The electron auxiliary layer 500 may be omitted, if desired (or required).

The cathode 220 may include (or be made of) a transparent conductor or an opaque conductor. The cathode 220 may include, for example, magnesium (Mg) or a magnesium alloy, and the magnesium alloy may include (or be), for example, a magnesium-silver alloy (MgAg), a double layer including a magnesium (Mg) layer and a silver (Ag) layer or the like, but the cathode is not limited thereto. The magnesium-silver alloy (MgAg) may be, for example, a co-deposited alloy of magnesium (Mg) and silver (Ag) co-deposited at a ratio of about 10:1 (Mg:Ag).

A capping layer and/or an encapsulation layer may be further included on the cathode 220. The capping layer may be on (or formed on) the entire surface of the cathode 220 to protect the cathode 220, and the encapsulation layer may prevent (or reduce) the permeation of oxygen and/or moisture from the outside to protect the organic light emitting diode device.

From the results of evaluating the driving voltage and efficiency of the organic light emitting diode device having a structure according to an embodiment of the present disclosure, it is confirmed that the driving voltage is decreased by about 0.5 V, and the efficiency may be increased by about 20%.

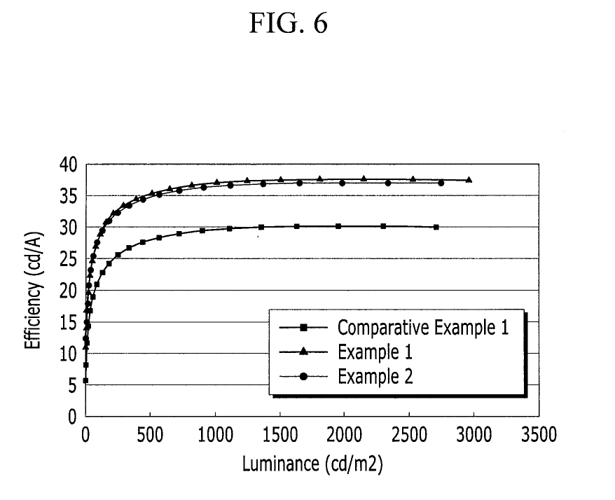

For example, FIG. 6 is a graph showing the efficiency of organic light emitting diode devices according to Example 1, Example 2, and Comparative Example 1.

Example 1 used a host having a HOMO level of 5.1 eV and a LUMO level of 2.2 eV, and a F4-TCNQ dopant as the first hole transport auxiliary layer; and a host having a HOMO level of 5.3 eV and a LUMO level of 2.4 eV, and a F4-TCNQ dopant as the second hole transport auxiliary layer. Example 2 used a host having a HOMO level of 5.2 eV and a LUMO level of 2.3 eV, and a F4-TCNQ dopant as the first hole transport auxiliary layer; and a host having a HOMO level of 5.4 eV and a LUMO level of 2.5 eV, and a F4-TCNQ dopant as the second hole transport auxiliary layer. Comparative Example 1 included a single hole transport auxiliary layer including a host having a HOMO level of 5.1 eV and a LUMO level of 2.2 eV, and a F4-TCNQ dopant. The single hole transport auxiliary layer had the same thickness as in the first hole transport auxiliary layers according to Examples 1, 2.

Referring to FIG. 6, it is confirmed that the organic light emitting diode devices according to Examples 1, 2 exhibited improved efficiency and, at the same, luminance, as compared to the organic light emitting diode device according to Comparative Example 1.

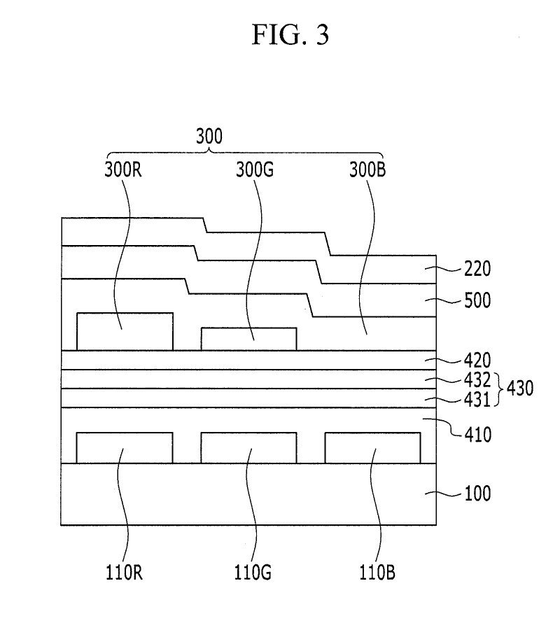

FIG. 3 is a cross-sectional view showing the organic light emitting diode device according to another embodiment.

FIG. 3 shows three pixels including a red pixel expressing red (e.g., configured to emit red light), a green pixel expressing green (e.g., configured to emit green light), and a blue pixel expressing blue (e.g., configured to emit blue light), together. A combination of red, green, and blue is one example of a combination of primary colors for expressing full color, and the red pixel, the green pixel, and the blue pixel may be considered basic pixels for expressing full color. Three pixels are grouped in one and are repeated along a row and along a column according to one embodiment.

Referring to FIG. 3, a red pixel anode 110R, a green pixel anode 110G, and a blue pixel anode 110B are on (or formed on) a thin film transistor substrate 100 including (or formed with) a thin film transistor (TFT) and wires. The hole injection layer (HIL) 410, the hole transport layer (HTL) 420, and the hole transport auxiliary layer 430 are (or are formed as) a common layer on one surface of a red pixel anode 110R, a surface of a green pixel anode 110G, and a surface of a blue pixel anode 110B. However, the present disclosure is not limited thereto, but at least one of the hole injection layer (HIL) 410, the hole transport layer (HTL) 420, and the hole transport auxiliary layer 430 may be on (or formed on) a part (or a portion) of the red pixel, the green pixel, and the blue pixel. The organic light emitting diode device of FIG. 3 includes a hole transport auxiliary layer 430 including a first hole transport auxiliary layer 431 and a second hole transport auxiliary layer 432, as described above with respect to FIG. 1.

An emission layer 300 is on (or formed on) one surface of a hole transport layer (HTL) 420, and the emission layer 300 includes a red emission layer 300R of the red pixel, a green emission layer 300G of the green pixel, and a blue emission layer 300B as (or formed as) a common layer with the red pixel, the green pixel and the blue pixel. By using a blue emission layer 300B as a common layer, the patterning of a blue emission layer 300B may be omitted, so the process of forming the organic light emitting diode device may be simplified.

An electron auxiliary layer 500 and a cathode 220 are on (or formed on) one surface of the emission layer 300.

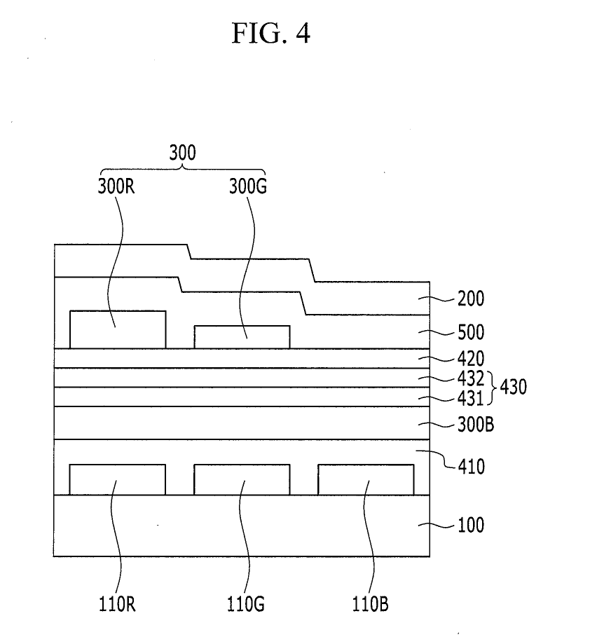

FIG. 4 is a cross-sectional view showing an organic light emitting diode device according to yet another embodiment.

Similarly to the embodiment described above with respect to FIG. 3, the organic light emitting diode device shown in FIG. 4 includes a thin film transistor substrate 100, a red pixel anode 110R, a green pixel anode 110G, and a blue pixel anode 110B, a hole injection layer (HIL) 410, a hole transport layer (HTL) 420, and a hole transport auxiliary layer 430, an emission layer 300, an electron auxiliary layer 500, and a cathode 220.

However, unlike the embodiment described above with respect to FIG. 3, the common layer of the blue emission layer 300B is between the hole injection layer (HIL) 410 and the hole transport auxiliary layer 430.

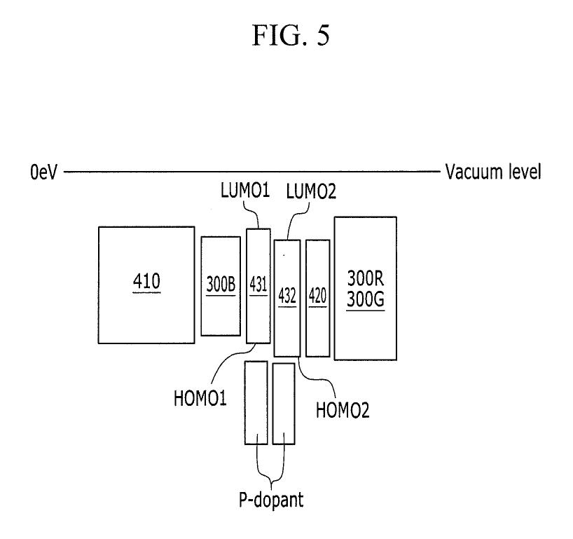

FIG. 5 is a schematic view showing one example of energy levels of the organic light emitting diode device shown in FIG. 4.

Referring to FIG. 5, the first hole transport auxiliary layer 431 and the second hole transport auxiliary layer 432 each includes a host and a p-type dopant, and the HOMO level (HOMO2) of the second hole transport auxiliary layer 432 may be higher than the HOMO level (HOMO1) of the first hole transport auxiliary layer 431. As described above, by including the first hole transport auxiliary layer 431 and the second hole transport auxiliary layer 432 having different HOMO levels, the electron mobility is effectively suppressed (or reduced), and the hole mobility is effectively increased, thereby decreasing the driving voltage and improving the efficiency of the organic light emitting diode device. The hole transport layer (HTL) 420 may include the same material as the host of the second hole transport auxiliary layer 432 (e.g., the second host).

The host of the first hole transport auxiliary layer 431 and the host of the second hole transport auxiliary layer 432 may each have a HOMO level of about 5.0 eV to about 5.5 eV and may be satisfied with, for example, Relationship Equation 1. For example, the first host may have a first HOMO level having an energy of about 5.0 eV to about 5.5 eV (or less than about 5.5 eV) and the second host may have a second HOMO level having an energy of about 5.0 eV (or more than 5.0 eV) to about 5.5 eV.

5.0 eV≦first HOMO level 5 second HOMO level≦5.5 eV Relationship Equation 1

The p-type dopant may be selected from, for example, a quinone derivative, a metal oxide, a cyano-containing compound, or a combination thereof, but the present disclosure is not limited thereto. The quinone compound may include, for example, tetracyanoquinone dimethane (TCNQ), 2,3,5,6-tetrafluoro-tetracyano-1,4-benzoquinone dimethane (F4-TCNQ), or a combination thereof; the metal oxide may include, for example, a tungsten oxide, a molybdenum oxide, or a combination thereof; the cyano-containing compound may include, for example, the compound HT-D1, but the present disclosure is not limited thereto.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting diode device, comprising:
an anode;
a hole auxiliary layer on one side of the anode;
an emission layer on one side of the hole auxiliary layer; and
a cathode on one side of the emission layer,
the hole auxiliary layer comprising:
a hole injection layer;
a hole transport layer;
a first hole transport auxiliary layer between the hole injection layer and the hole transport layer and comprising a first p-type dopant and a first host having a first HOMO level; and
a second hole transport auxiliary layer between the hole injection layer and the hole transport layer and comprising a second p-type dopant and a second host having a second HOMO level different from the first HOMO level.

2. The organic light emitting diode device of claim 1, wherein the second HOMO level is higher than the first HOMO level.

3. The organic light emitting diode device of claim 1, wherein the hole transport layer comprises a host that is the same as the second host.

4. The organic light emitting diode device of claim 1, wherein the second hole transport auxiliary layer directly contacts the hole transport layer.

5. The organic light emitting diode device of claim 1, wherein the first HOMO level and the second HOMO level are each about 5.0 eV to about 5.5 eV.

6. The organic light emitting diode device of claim 1, wherein the hole auxiliary layer is stacked in order of the hole injection layer, the first hole transport auxiliary layer, the second hole transport auxiliary layer, and the hole transport layer.

7. The organic light emitting diode device of claim 6, further comprising a blue common layer between the hole injection layer and the first hole transport auxiliary layer.

8. The organic light emitting diode device of claim 1, wherein the first p-type dopant of the first hole transport auxiliary layer is included in an amount of about 0.01 to about 20 parts by weight based on 100 parts by weight of the first host.

9. The organic light emitting diode device of claim 1, wherein the second p-type dopant of the second hole transport auxiliary layer is included in an amount of about 0.01 to about 20 parts by weight based on 100 parts by weight of the second host.

10. The organic light emitting diode device of claim 1, wherein the first p-type dopant or the second p-type dopant comprises a quinone derivative, a metal oxide, a cyano-containing compound, or a combination thereof.

11. The organic light emitting diode device of claim 10, wherein the first p-type dopant or the second p-type dopant comprises tetracyanoquinone dimethane (TCNQ), 2,3,5,6-tetrafluoro-tetracyano-1,4-benzoquinone dimethane (F4-TCNQ), a tungsten oxide, a molybdenum oxide, or a combination thereof.
